(19) United States
(12) Patent Application Publication
(10) Pub. No.: US 2008/0090411 A1
(43) Pub. Date: Apr. 17, 2008

(54) Method of manufacturing a semiconductor device

(75) Inventors: Jik Ho Cho, Anyang-si (KR); Tae Kyung Kim, Cheongju-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/801,290

(22) Filed: May 9, 2007

(30) Foreign Application Priority Data
Oct. 17, 2006 (KR) 2006-100874

(51) Int. Cl. H01L 21/4763

(52) U.S. Cl. 438/648; 257/E21.495

(57) ABSTRACT

A method of manufacturing a semiconductor device is disclosed. The method includes the steps of forming a first insulating film having a contact plug on an upper portion of a semiconductor substrate; forming a second insulating film on an upper portion of the first insulating film and the contact plug; etching the second insulating film formed on the upper portion of the contact plug to expose the upper portion of the contact plug; and, forming a glue film and a metal film on the upper portion of the resulting surface on the semiconductor substrate including the metal wiring contact hole.

### CROSS-REFERENCE TO RELATED APPLICATION

The priority of Korean patent application number 10-2006-100874, filed on Oct. 17, 2006, the disclosure of which is incorporated by reference in its entirety, is claimed.

### BACKGROUND OF THE INVENTION

The invention relates generally to a method of manufacturing a semiconductor device and, more particularly, to a method that prevents the loss of a contact plug caused by an etching gas used when over-etching metal wirings.

As a device becomes more highly integrated, the widths of a contact plug and metal wirings decrease. A method of forming metal wirings in a general flash memory device is described below.

An insulating film having a drain contact hole is formed on the upper portion of a semiconductor substrate having a predetermined structure, and then a doped poly-silicon film is formed such that the drain contact hole is filled therewith. The poly-silicon film is polished until the upper portion of the insulating film is reached, thereby forming a contact plug. Thereafter, a glue layer is formed on the upper portion of the semiconductor substrate including the contact plug. In this case, the glue film has a laminated structure including a titanium (Ti) film and a titanium nitride (TiN) film.

Then, tungsten (W) is formed on the upper portion of the glue film using Chemical Vapor Deposition (CVD), and then the tungsten and the glue film are etched in turn to form metal wirings. The tungsten is etched using a dry plasma etching process with SF₆ gas, and an over-etching process is performed for a certain time in order to remove the remaining tungsten.

However, when the metal wirings are formed through the above-described etching process, the glue film may be exposed upon the over-etching process. In this case, a part of the glue film is attacked due to the plasma etching process, causing a local loss of the glue film. Thus, the contact plug is also attacked by the SF₆ etching gas. The loss of a portion of the contact plug creates a short circuit between the metal wirings and the contact plug.

In order to resolve the above-described problem, methods of increasing the thickness of the glue film (i.e., Ti and TiN films) or decreasing the target of the over-etching process (i.e., tungsten) have been considered.

However, when increasing the thickness of the glue film, the overall thickness of the metal wirings also increases, thereby increasing the capacitance thereof. When the over-etching target of tungsten is reduced, the tungsten is not perfectly removed, thereby causing a bridge between the metal wirings. Furthermore, when misalignment occurs between the contact plug and the metal wirings upon etching tungsten, the problem related to the bridge between the metal wirings becomes more serious.

### SUMMARY OF THE INVENTION

To solve these problems, a method of manufacturing a semiconductor device is disclosed which prevents the loss of a contact plug caused by an etching gas used when over-etching metal wirings.

To achieve these objects, there is provided a method of manufacturing a semiconductor device including the steps of forming a first insulating film having a contact plug on an upper portion of a semiconductor substrate; forming a second insulating film on an upper portion of the first insulating film and the contact plug; etching the second insulating film formed on the upper portion of the contact plug to expose the upper portion of the contact plug; and, forming a glue film and a metal film on the upper portion of the resulting surface on the semiconductor substrate.

Furthermore, to achieve these objects, there is provided a method of manufacturing a semiconductor device including the steps of forming a first insulating film having a contact plug on an upper portion of a semiconductor substrate; forming a second insulating film on an upper portion of the first insulating film and the contact plug; removing a portion of the first and second insulating films to form a metal wiring contact hole apart from the contact plug by performing an etching process, and etching the second insulating film formed on an upper portion of the contact plug during the etching process to expose the upper portion of the contact plug; and, forming a glue film and a metal film on the upper portion of the resulting surface on the semiconductor substrate including the metal wiring contact hole.

### BRIEF DESCRIPTION OF THE DRAWINGS

The accompanying drawings illustrate embodiments of the invention and together with the description serve to explain the principle of the invention. In the drawings:

FIGS. 1A to 1F are schematic cross-sectional diagrams illustrating a method of manufacturing a semiconductor device according to an embodiment of the invention; and

FIG. 2 is a schematic cross-sectional diagram illustrating the misalignment between a contact plug and metal wirings according to an embodiment of the invention.

### DESCRIPTION OF SPECIFIC EMBODIMENTS

Reference is made in detail to embodiments of the invention, examples of which are illustrated in the accompanying drawings.

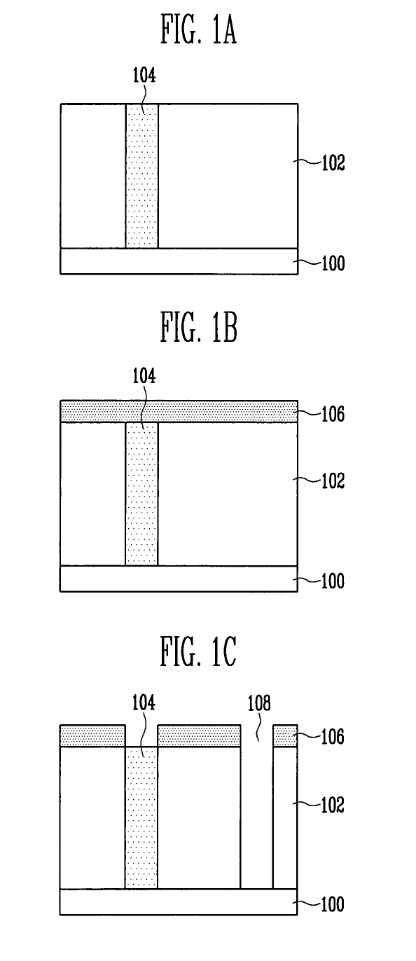

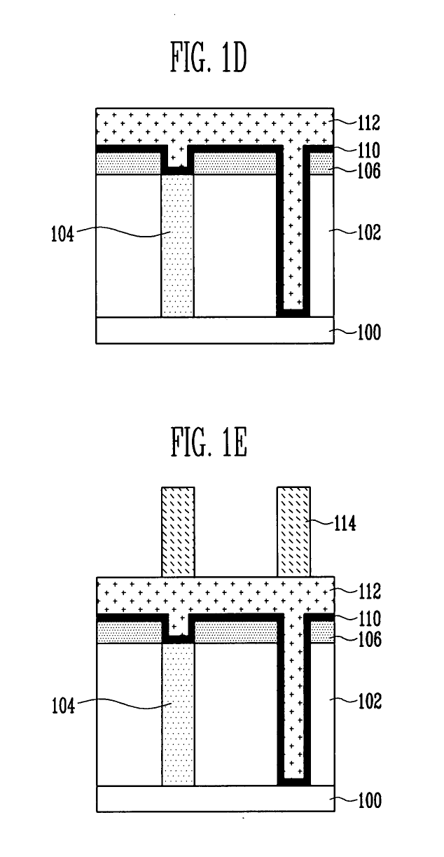

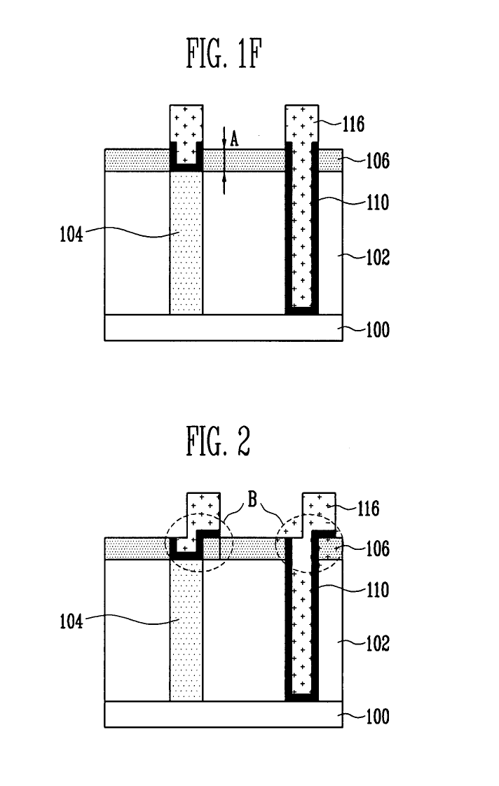

Referring to FIG. 1, a first insulating film 102 is formed on the upper portion of a semiconductor substrate 100 having a predetermined structure (not shown) including an element isolating film, a gate, a source and a drain. Then, the first insulating film 102 is etched until a part of the semiconductor substrate 100 is exposed through a photograph and etching process, thereby forming a drain contact hole. A conductive film is formed on the upper portion of the semiconductor substrate 100 and the first insulating film 102 such that the drain contact hole is filled with the conductive film. Then the first insulating film 102 is polished until the upper portion of the first insulating film 102 is exposed, thereby forming a contact plug 104. The conductive film can be a poly-silicon film

Referring to FIG. 1B, a second insulating film 106 is formed on the upper portion of the first insulating film and the contact plug 104. The second insulating film can be a silicon oxide film, and its thickness is selected based on the target of over-etching process used to form metal wirings, which follows.

Referring to FIG. 1C, an etching process removing parts of the second insulating film 106 and the first insulating film 102 is performed to form a metal wiring contact hole 108 apart from the contact plug 104. During the etching process, the second insulating film 106 formed on the upper portion of the contact plug 104 is also etched to expose the upper portion of the contact plug 104.

Referring to FIG. 1D, a glue film 110 is formed on the resulting surface above the semiconductor substrate 100, including the metal wiring contact hole 108. The glue film 110 can have a laminated structure including a titanium (Ti) film and a titanium nitride (TiN) film. A metal film 112 is formed on the upper portion of the semiconductor substrate 100 including the glue film 110 such that the metal wiring contact hole 108 is filled with the metal film 112. The metal film 112 can be made of tungsten using Chemical Vapor Deposition (CVD).

Referring to FIG. 1E, a photoresist pattern 114 is formed on the upper portion of the semiconductor substrate 100 including the metal film 112 such that a part of the metal film 112 is exposed.

Referring to FIG. 1F, the metal film 112 and the glue film 110 are etched using the photoresist pattern 114 as a mask to form metal wirings 116, and then the photoresist pattern 114 is removed. The metal film 112 can be fully removed using an over-etching process with SF₆ gas.

The second insulating film 106 having a constant thickness (A) remains on the upper portion of the contact plug 104 during the over-etching process for forming the metal wirings 116, thereby preventing the loss of the contact plug 104 due to SF₆ etching gas.

Furthermore, although the thickness of the glue film 110 decreases, the second insulating film 106 having a constant thickness (A) remains on the upper portion of the contact plug 104, thereby preventing the loss of the contact plug 104. Thus, the thickness of the glue film 110 can be decreased or the thickness of the metal film 112 can be increased, thereby making a reduction of the resistance or capacitance of the metal wirings 116 possible.

Referring to FIG. 2, the metal film (reference number 112 of FIG. 1E) is etched using a misaligned photoresist pattern as a mask to form the metal wirings 116. In this case, the metal film is removed through an over-etching process using SF₆ gas. By forming the metal wirings using the misaligned photoresist pattern, a misalignment B occurs between the contact plug 104 and the metal wirings 116.

Although misalignment B occurs between the contact plug 104 and the metal wirings 116, the glue film 110 and the metal film which have a constant thickness still remain on the upper portion of the contact plug 104, thereby preventing the loss of the contact plug 104 due to SF₆ etching gas.

The method described above has the following advantages.

First, a second insulating film having a constant thickness remains on the upper portion of a contact plug during the over-etching process for forming the metal wirings, thereby preventing the loss of the contact plug 104 due to SF₆ etching gas.

Second, although the thickness of a glue film decreases, the second insulating film having a constant thickness remains on the upper portion of a contact plug, thereby preventing the loss of the contact plug.

Third, it is possible to decrease the thickness of the glue film or increase the thickness of the metal film, thereby making a reduction of the resistance or capacitance of the metal wirings possible.

Fourth, although misalignment occurs between the contact plug and the metal wirings, the glue film and the metal film which have a constant thickness still remain on the upper portion of the contact plug, thereby preventing the loss of the contact plug 104 due to SF₆ etching gas.

Fifth, the disclosed method resolves the above-described problems completely, thereby improving yield.

Although preferred embodiments have been disclosed for illustrative purposes, those skilled in the art will appreciate that various modifications, additions, and substitutions are possible without departing from the scope and spirit of the invention as defined by the accompanying claims.

What is claimed is:

1. A method of manufacturing a semiconductor device, comprising:
forming a first insulating film having a contact plug on an upper portion of a semiconductor substrate;
forming a second insulating film on an upper portion of the first insulating film and the contact plug;
etching the second insulating film formed on an upper portion of the contact plug to expose the upper portion of the contact plug; and,
forming a glue film and a metal film on the upper portion of the resulting surface on the semiconductor substrate.

2. The method as set forth in claim 1, wherein the second insulating film comprises an oxide film.

3. The method as set forth in claim 1, wherein the glue film comprises a laminated structure of a titanium film and a titanium nitride film.

4. The method as set forth in claim 1, wherein the metal film comprises tungsten formed using chemical vapor deposition.

5. A method of manufacturing a semiconductor device, comprising:
forming a first insulating film having a contact plug on an upper portion of a semiconductor substrate;
forming a second insulating film on an upper portion of the first insulating film and the contact plug;
removing a portion of the first and second insulating films to form a metal wiring contact hole apart from the contact plug by performing an etching process, and etching the second insulating film formed on an upper portion of the contact plug during the etching process to expose the upper portion of the contact plug; and,
forming a glue film and a metal film on the upper portion of the resulting surface on the semiconductor substrate including the metal wiring contact hole.

6. The method as set forth in claim 5, wherein the second insulating film comprises an oxide film.

7. The method as set forth in claim 5, wherein the glue film comprises a laminated structure of a titanium film and a titanium nitride film.

8. The method as set forth in claim 5, wherein the metal film comprises tungsten formed using chemical vapor deposition.
